(19) United States
(12) Patent Application Publication
(10) Pub. No.: US 2024/0332052 A1
(43) Pub. Date: Oct. 3, 2024

(54) WAFER HOUSING CONTAINER AND METHOD OF MANUFACTURING SEMICONDUCTOR DEVICE

(71) Applicant: Mitsubishi Electric Corporation, Tokyo (JP)

(72) Inventors: Mikihito SUZUKI, Tokyo (JP); Ryuji UENO, Tokyo (JP); Shotaro NAKAMURA, Tokyo (JP)

(73) Assignee: Mitsubishi Electric Corporation, Tokyo (JP)

(21) Appl. No.: 18/412,487

(22) Filed: Jan. 13, 2024

(30) Foreign Application Priority Data
Mar. 31, 2023 (JP) 2023-057743

(51) Int. Cl. H01L 21/673; H01L 21/683

(52) U.S. Cl. CPC H01L 21/67386; H01L 21/67346; H01L 21/67383; H01L 21/6838

(57) ABSTRACT

Provided is a wafer housing container capable of preventing rotation and floating of a wafer while high liquid removability is ensured. A wafer housing container includes two or more chassis frames stacked on each other and a wafer holding structure formed between the chassis frames. The wafer holding structure includes a plurality of arms extending from each of the chassis frames on both sides of the wafer holding structure, and sandwiches an outer edge portion of a wafer with the plurality of arms on one of the chassis frames on one side and the plurality of arms on the other one of chassis frames on the other side to hold the wafer.

### BACKGROUND OF THE INVENTION

### Field of the Invention

The present disclosure relates to a wafer housing container used in a semiconductor wafer process and a method of manufacturing a semiconductor device using the same.

### Description of the Background Art

A wafer housing container (also referred to as “a wafer carrier”) having a shape in consideration of liquid removability or drying characteristics is used in a process of cleaning a wafer, a wet process such as a film deposition process, or a drying process in a semiconductor wafer process. For example, Japanese Patent Application Laid-Open No. 2010-182797 discloses a wafer housing container having a small groove (slot) in which a wafer is housed and a large opening part. The wafer housing container (wafer carrier) is simply referred to as “a carrier” in some cases hereinafter.

### SUMMARY

The semiconductor wafer process in manufacturing a power device includes a process of polishing a back surface of a wafer to reduce a thickness of the wafer after making an element in a front surface of the wafer, for example. The wafer is shaved to have a thickness of approximately several tens micrometers to 200 μm by this process. The thin wafer has low strength, thus is easily warped. The thin wafer is light, thus easily floats up in liquid. These warp and floating of the wafer significantly occur as a diameter of the wafer gets larger.

When a wet process is performed on a wafer with warp or a wafer which easily floats up in liquid, there is concern that the wafer falls off a carrier or wafers attract each other by surface tension of the liquid and adhere to each other when the liquid is removed from the carrier. When the carrier housing the wafer is rocked in liquid, the wafer is disorderly rotated in the carrier, thus there is a problem that dust occurs due to friction between the wafer and the carrier.

An object of the present disclosure is to provide a wafer housing container capable of preventing rotation and floating of a wafer while ensuring high liquid removability.

A wafer housing container according to the present disclosure includes two or more chassis frames stacked on each other and at least one wafer holding structure formed between the chassis frames. The wafer holding structure includes a plurality or arms extending from the chassis frames on both sides of the wafer holding structure. The wafer holding structure sandwiches an outer edge portion of a wafer with the plurality of arms on one of the chassis frames on one side and the plurality of arms on another one of the chassis frames on another side to hold the wafer.

According to the wafer housing container according to the present disclosure, rotation and floating of a wafer can be prevented while high liquid removability is ensured. These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram illustrating a configuration of a wafer housing container according to an embodiment 1.

FIG. 2 is a diagram illustrating a configuration of one chassis frame.

FIG. 3 is a diagram for explaining a procedure of housing a wafer in the wafer housing container and a procedure of taking out the wafer from the wafer housing container according to the embodiment 1.

FIG. 4 is a diagram illustrating a configuration of a wafer housing container according to an embodiment 2.

FIG. 5 is a diagram illustrating a configuration of an intermediate chassis frame.

FIG. 6 is a diagram illustrating an exploded wafer housing container according to the embodiment 2.

FIG. 7 is a flow chart illustrating a method of manufacturing a semiconductor device according to an embodiment 3.

### DESCRIPTION OF THE PREFERRED EMBODIMENTS

### Embodiment 1

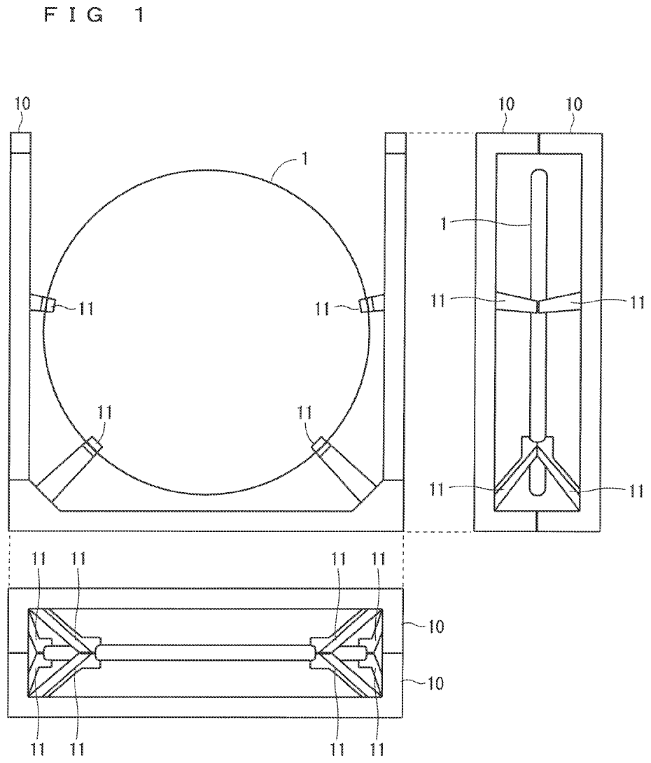

FIG. 1 is a diagram illustrating a configuration of a wafer housing container (carrier) according to an embodiment 1, and is a three-view drawing including a front view, a side view, and a bottom view of the carrier.

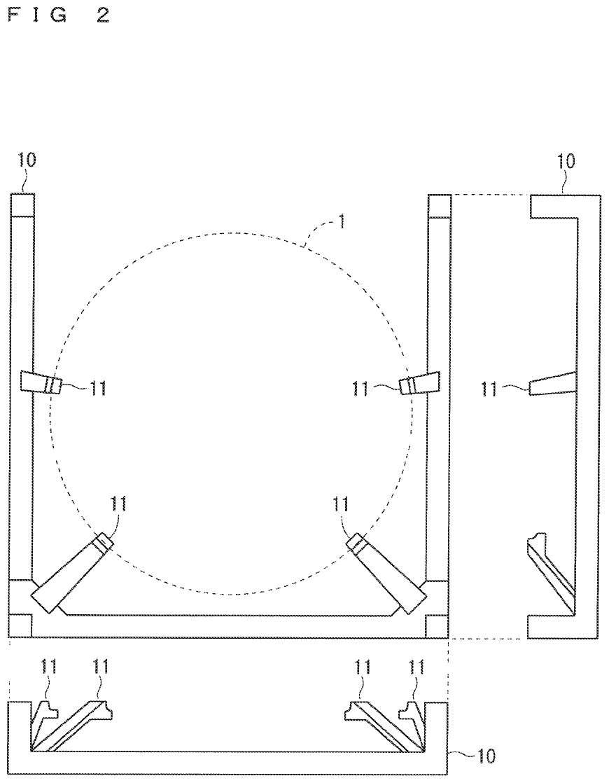

As illustrated in FIG. 1, the carrier according to the embodiment 1 is made up of two chassis frames 10 stacked on each other. FIG. 2 illustrates a configuration of one chassis frame 10. The chassis frame 10 includes a plurality of arms 11 extending toward an outer edge portion of a wafer 1 held by the arms 11.

Two chassis frames 10 are stacked and joined so that tip portions of the arms 11 face each other, thus a wafer holding structure of holding the wafer 1 is formed between the chassis frames 10. That is to say, the wafer holding structure includes the plurality of arms 11 extending from each of the chassis frames 10 on both sides of the wafer holding structure, and sandwiches an outer edge portion of the wafer 1 with the plurality of arms 11 on one of the chassis frames 10 on one side and the plurality of arms 11 on the other one of the chassis frames 10 on the other side to hold the wafer 1. It is preferable that the plurality of arms 11 hold a bevel part as an outermost edge portion of the wafer 1 and do not have contact with a main surface of the wafer 1 serving as a formation region of the semiconductor device. A material having chemical-proof properties such as PEEK or PFA or conductive resin, from a viewpoint of preventing static electrification of the wafer 1, may be used as a material of the chassis frame 10.

Two chassis frames 10 constituting the wafer housing container can be attached to and detached from each other. That is to say, the wafer housing container can be divided into two chassis frames 10.

As shown by FIG. 1, the wafer 1 housed in the wafer housing container has contact with only the arm 11 but does not contact with a body part of the chassis frame 10. As shown by the side view in FIG. 1, the plurality of arms 11 are disposed not to have contact with a position located on a lowermost side of the outer edge portion of the wafer 1 while the wafer housing container is located to stand the wafer 1 held by the wafer holding structure (that is to say, the main surface of the wafer 1 is directed to a lateral side). The plurality of arms 11 is disposed to be located so that a position located on a lowermost side of the outer edge portion of the wafer 1 is located to be higher than a bottom of the wafer housing container while the wafer housing container is located to stand the wafer 1. Furthermore, four sides of a lateral portion of the wafer 1 held by the wafer holding structure are opened in the wafer housing container.

High liquid removability of the wafer housing container is ensured by these configurations. For example, four sides of the lateral portion of the wafer 1 held by the wafer holding structure are opened, thus disturbance of a liquid flow can be suppressed even when a liquid flow is applied from any direction to the wafer housing container in a wet process, and a liquid flow of a cleaning liquid or a film deposition liquid can be uniformized on the wafer 1. Remaining liquid on the wafer 1 is suppressed when the wafer housing container is pulled out of a liquid tank or the wafer is dried, and occurrence of spots, for example, can be prevented.

The plurality of arms 11 sandwich the wafer 1, thus high retainability of the wafer 1 can be ensured. Warp and flexure of the housed wafer 1 are suppressed, and detachment, rotation, and floating of the wafer 1 are prevented. Even when the plurality of wafers 1 are housed in the wafer housing container (a configuration capable of housing the plurality of wafers 1 is described in an embodiment 2), prevented is that the wafers 1 attract each other by surface tension of the liquid and adhere to each other when the liquid is removed from the wafer housing container.

As shown by the side view in FIG. 1, at least one of the plurality of arms 11 is preferably disposed to have contact with a position located on an upper side of a middle portion of the wafer 1 while the wafer housing container is disposed to stand the wafer 1 held by the wafer holding structure. Accordingly, detachment, rotation, and floating of the wafer 1 are prevented more reliably.

Described are a procedure of housing the wafer 1 in the wafer housing container and a procedure of taking out the wafer 1 from the wafer housing container according to the embodiment 1. Herein, two chassis frames 10 are referred to as “the first chassis frame 10” and “the second chassis frame 10” for distinction.

The procedure of housing the wafer 1 in the wafer housing container is as follows.

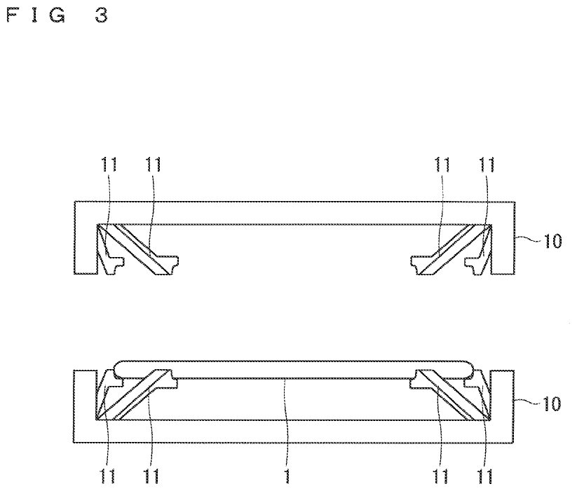

(1) The first chassis frame 10 is disposed so that the plurality of arms 11 are directed upward, and the wafer 1 held by vacuum tweezers or edge clamp tweezers, for example, is disposed on the arms 11 as illustrated in FIG. 3.

(2) The second chassis frame 10 is stacked on the first chassis frame 10 and joined while the plurality of arms 11 are directed downward. At this time, the arm 11 of the first chassis frame 10 and the arm 11 of the second chassis frame 10 face each other and the arm 11 of the first chassis frame 10 and the arm 11 of the second chassis frame 10 sandwich the chassis frame 10.

(3) The wafer housing container stands upright to stand the wafer 1.

It is sufficient that a reverse procedure of housing the wafer 1 is performed to take out the wafer 1 from the wafer housing container.

### Embodiment 2

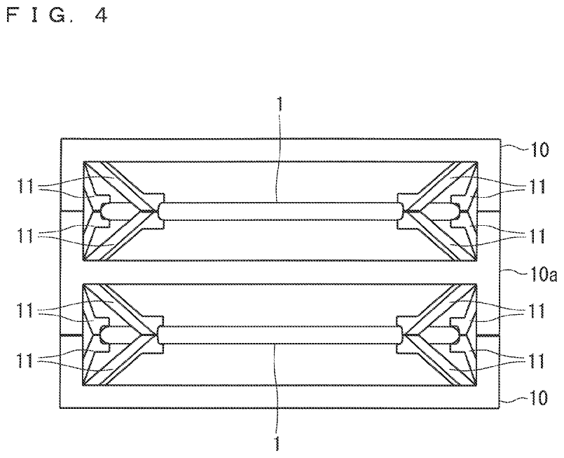

A wafer housing container capable of housing the plurality of wafers 1 is described in an embodiment 2. FIG. 4 is a diagram illustrating a configuration of a wafer housing container (carrier) according to the embodiment 2.

As illustrated in FIG. 4, the wafer housing container according to the embodiment 2 has the wafer holding structure that three chassis frames 10 disposed to be stacked on each other are included and the wafer 1 is held between the chassis frames 10. Thus, the wafer housing container in FIG. 4 has two wafer holding structures.

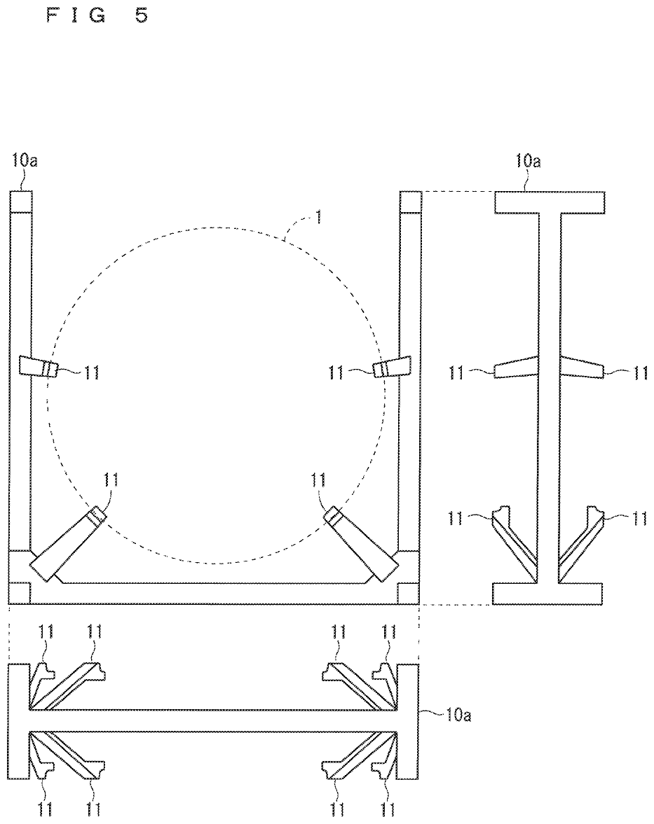

The intermediate chassis frame 10a sandwiched between the chassis frames 10 on both ends in three chassis frames 10 disposed to be stacked on each other includes the plurality of arms 11 on both sides. Thus, the intermediate chassis frame 10a can form the wafer holding structure on both sides thereof. FIG. 5 illustrates a configuration of the intermediate chassis frame 10a.

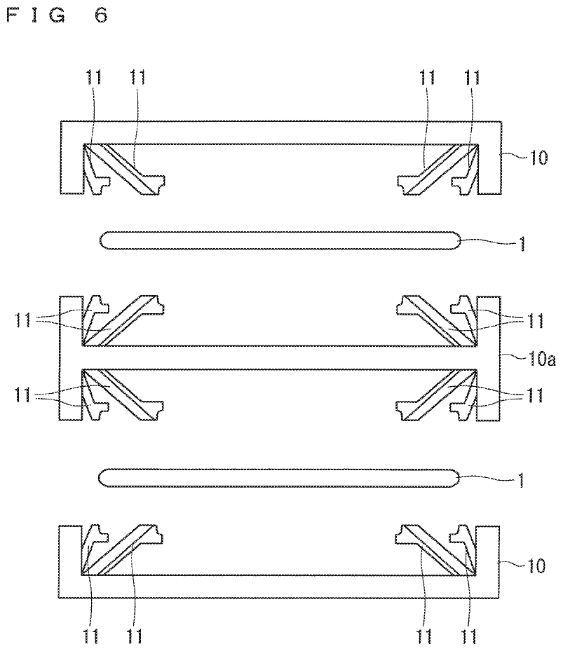

The chassis frame 10 can be attached to and detached from each other, and the wafer housing container illustrated in FIG. 4 can be divided as illustrated in FIG. 6. FIG. 4 and FIG. 6 illustrate the configuration that only one intermediate chassis frame 10a is included, however, the number of the intermediate chassis frames 10a is increased, the number of wafer holding structures is increased, and the number of wafers 1 which can be held can be increased. That is to say, the number of wafer holding structures can be changed by changing the number of intermediate chassis frames 10a. The wafer housing container can be divided, thus there is a merit that details of the wafer housing container can be easily cleaned.

An effect similar to that in the embodiment 1 is obtained also in the embodiment 2.

Described in the embodiments 1 and 2 is the configuration that a shape of the chassis frame 10 in a plan view is a U-like shape and the side thereof facing the main surface of the wafer 1 in the wafer housing container is opened, however, the side thereof facing the main surface of the wafer 1 may not be opened. For example, the side of the chassis frame 10 facing the main surface of the wafer 1 may have a plate-like shape. Particularly, when the U-like shaped chassis frame 10 is used in the wafer housing container housing the plurality of wafers 1 according to the embodiment 2, only the main surface on one side of the wafer 1 located on both ends faces the other wafer 1 and both main surfaces of the wafer 1 located in the intermediate portion face the other wafer 1, thus a difference of a liquid flow easily occurs between the wafer 1 on both ends and the intermediate wafer 1. In contrast, when the plate-like chassis frame 10 is used, both main surfaces of all of the wafers 1 face the flat plate of the chassis frame 10, thus suppressed is occurrence of difference of a surrounding liquid flow between the wafer 1 on both ends and the intermediate wafer 1.

Each diagram illustrates the chassis frame 10 made up of an angulated member, however, the member constituting the chassis frame 10 may be chamfered.

### Embodiment 3

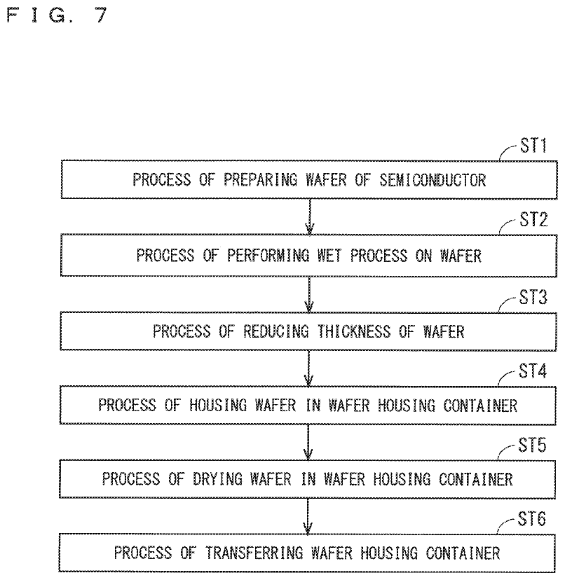

FIG. 7 is a flow chart illustrating a method of manufacturing the semiconductor device according to an embodiment 3. The wafer housing container described in the embodiments 1 and 2 is used for the method of manufacturing the semiconductor device according to the embodiment 3.

Specifically, the method of manufacturing the semiconductor device according to the embodiment 3 includes processes described hereinafter.

Firstly performed is a process of preparing the wafer 1 of a semiconductor made by slicing an ingot (Step ST1). Performed next is a process of performing a wet process such as cleaning or film deposition on the wafer 1 (Step ST2). Next, one surface of the wafer 1 is shaved to perform a processing of reducing the thickness of the wafer 1 (Step ST3). Subsequently performed is a process of housing the wafer 1 in the wafer housing container according to the embodiment 1 or 2 (Step ST4). Performed next is a process of drying the wafer 1 in the wafer housing container (Step ST5). Performed then is a process of transferring the wafer housing container housing the wafer 1 (Step ST6).

The processing of drying the wafer 1 is performed while the wafer housing container is located to stand the wafer 1. The method of drying the wafer 1 includes natural drying.

According to the method of manufacturing the semiconductor device according to the embodiment 3, disturbance of a liquid flow in a wet process such as cleaning or film-deposition of the wafer 1 and remaining liquid in a process of drying the wafer 1 can be prevented, thus such a configuration can contribute to stable production of the semiconductor device.

Each embodiment can be arbitrarily combined, or each embodiment can be appropriately varied or omitted.

### APPENDIX

The aspects of the present disclosure are collectively described hereinafter as appendixes.

### Appendix 1

A wafer housing container, comprising:
two or more chassis frames stacked on each other; and
at least one wafer holding structure formed between the chassis frames, wherein
the wafer holding structure includes a plurality of arms extending from each of the chassis frames on both sides of the wafer holding structure, and sandwiches an outer edge portion of a wafer with the plurality of arms on one of the chassis frames on one side and the plurality of arms on another one of the chassis frames on another side to hold the wafer.

### Appendix 2

The wafer housing container according to Appendix 1, wherein the two or more chassis frames can be attached to and detached from each other.

### Appendix 3

The wafer housing container according to Appendix 1, comprising
the three or more chassis frames, wherein
at least one intermediate chassis frame in the three or more chassis frames stacked on each other includes the plurality of arms on both sides, and the wafer holding structure is formed on both sides of the intermediate chassis frame.

### Appendix 4

The wafer housing container according to Appendix 3, wherein
the three or more chassis frames can be attached to and detached from each other, and
a total number of the wafer holding structures can be changed by changing a total number of intermediate chassis frames.

### Appendix 5

The wafer housing container according to any one of Appendixes 1 to 4, wherein
four sides of a lateral portion of the wafer held by the wafer holding structure are opened.

### Appendix 6

The wafer housing container according to any one of Appendixes 1 to 5, wherein
the plurality of arms are disposed not to have contact with a position located on a lowermost side of the outer edge portion of the wafer while the wafer housing container is located so that a main surface of the wafer held by the wafer holding structure is directed to a lateral side.

### Appendix 7

The wafer housing container according to any one of Appendixes 1 to 6, wherein
the plurality of arms are disposed to be located so that a position located on a lowermost side of the outer edge portion of the wafer is located to be higher than a bottom of the wafer housing container while the wafer housing container is located so that a main surface of the wafer held by the wafer holding structure is directed to a lateral side.

### Appendix 8

The wafer housing container according to any one of Appendixes 1 to 7, wherein
at least one of the plurality of arms is disposed to have contact with a position located on an upper side of a middle portion of the wafer while the wafer housing container is located so that a main surface of the wafer held by the wafer holding structure is directed to a lateral side.

### Appendix 9

The wafer housing container according to any one of Appendixes 1 to 8, wherein
the plurality of arms hold a bevel part as an outermost edge portion of the wafer and do not have contact with a main surface of the wafer.

### Appendix 10

A method of manufacturing a semiconductor device, comprising:
a step of preparing a wafer of a semiconductor;
a step of performing a wet process on the wafer;
a step of shaving one surface of the wafer and reducing a thickness of the wafer;
a step of housing the wafer whose thickness has been reduced in the wafer housing container according to any one of Appendixes 1 to 9;
a step of drying the wafer in the wafer housing container; and
a step of transferring the wafer housing container.

While the invention has been shown and described in detail, the foregoing description is in all aspects illustrative and not restrictive. It is therefore understood that numerous modifications and variations can be devised without departing from the scope of the invention.

What is claimed is:

1. A wafer housing container, comprising:
two or more chassis frames stacked on each other; and
at least one wafer holding structure formed between the chassis frames, wherein
the wafer holding structure includes a plurality of arms extending from each of the chassis frames on both sides of the wafer holding structure, and sandwiches an outer edge portion of a wafer with the plurality of arms on one of the chassis frames on one side and the plurality of arms on another one of the chassis frames on another side to hold the wafer.

2. The wafer housing container according to claim 1, wherein
the two or more chassis frames can be attached to and detached from each other.

3. The wafer housing container according to claim 1, comprising
the three or more chassis frames, wherein
at least one intermediate chassis frame in the three or more chassis frames stacked on each other includes the plurality of arms on both sides, and the wafer holding structure is formed on both sides of the intermediate chassis frame.

4. The wafer housing container according to claim 3, wherein
the three or more chassis frames can be attached to and detached from each other, and
a total number of the wafer holding structures can be changed by changing a total number of intermediate chassis frames.

5. The water housing container according to claim 1, wherein
four sides of a lateral portion of the wafer held by the wafer holding structure are opened.

6. The wafer housing container according to claim 1, wherein
the plurality of arms are disposed not to have contact with a position located on a lowermost side of the outer edge portion of the wafer while the wafer housing container is located so that a main surface of the wafer held by the wafer holding structure is directed to a lateral side.

7. The wafer housing container according to claim 1, wherein
the plurality of arms are disposed to be located so that a position located on a lowermost side of the outer edge portion of the wafer is located to be higher than a bottom of the wafer housing container while the wafer housing container is located so that a main surface of the wafer held by the wafer holding structure is directed to a lateral side.

8. The wafer housing container according to claim 1, wherein
at least one of the plurality of arms is disposed to have contact with a position located on an upper side of a middle portion of the wafer while the wafer housing container is located so that a main surface of the wafer held by the wafer holding structure is directed to a lateral side.

9. The wafer housing container according to claim 1, wherein
the plurality of arms hold a bevel part as an outermost edge portion of the wafer and do not have contact with a main surface of the wafer.

10. A method of manufacturing a semiconductor device, comprising:
a step of preparing a wafer of a semiconductor;
a step of performing a wet process on the wafer,
a step of shaving one surface of the wafer and reducing a thickness of the wafer;
a step of housing the wafer whose thickness has been reduced in the wafer housing container according to claim 1;
a step of drying the wafer in the wafer housing container; and
a step of transferring the wafer housing container.
